(19) United States
(12) Patent Application Publication
(10) Pub. No.: US 2007/0189953 A1
(43) Pub. Date: Aug. 16, 2007

(54) Method for obtaining carbon nanotubes on supports and composites comprising same

(75) Inventors: Jinbo Bai, Antony (FR); Li-Jie Ci, Antony (FR); Zhig-Gang Zhao, Antony (FR)

Correspondence Address: NIXON & VANDERHYE, PC, 901 NORTH GLEBE ROAD, 11TH FLOOR, ARLINGTON, VA, 22203, US

(73) Assignee: Centre National De La Recherche Scientifique (CNRS), Paris (FR)

(21) Appl. No.: 10/587,546

(22) PCT Filed: Jan. 21, 2005
(86) PCT No.: PCT/FR05/00201

§ 371 Date: Jan. 5, 2007

(30) Foreign Application Priority Data
Jan. 30, 2004 (FR) 0400916
Apr. 29, 2004 (FR) 0404586

(51) Int. Cl. C01B 31/00; C23C 16/00

(52) U.S. Cl. 423/414; 977/742; 427/249.1

(57) ABSTRACT

The invention concerns a method for obtaining carbon nanotubes by CVD growth on nano/micrometric supports, characterized in that it comprises: adding a carbon source compound containing a catalyst, under an inert gas and hydrogen current. The invention is applicable to the manufacture of multiple-scale composites.

One subject of the invention is a process for obtaining carbon nanotubes (abbreviated to CNTs) on supports, more especially using the CVD (Chemical Vapor Deposition) method. Another subject of the invention is their applications, in particular for producing composites, and also the uses of these composites.

It is known that carbon nanotubes have been proposed as fillers for reinforcing structures of composites. However, despite the very useful properties of CNTs, most experimental results from their composites have, hitherto, shown a rather mediocre reinforcing effect. The main reasons that may be mentioned include the poor quality of the CNTs used, the deterioration of the properties of the CNTs during their purification, the poor dispersion and/or the destruction of the CNTs during dispersion, the weak interface between the CNTs and the matrices, the difficulty of aligning the CNTs in the matrices and, often, too high a mass fraction of CNTs added.

Composites comprising conventional (microscale) reinforcements that have been developed over a few decades have not had very extensive applications in particular because of the weak interface between the reinforcements and the matrix. The damage mechanism usually observed is lack of cohesion and/or cracking at the interface due to stress concentrations or to stresses caused by the difference in their properties and in their thermal expansion coefficients.

It is often necessary to use a high reinforcement content in order to improve the properties of matrices, which entails many difficulties during processing, during forming, or possibly during machining and recycling of the composites. The applications of these composites are therefore limited owing to their brittleness. In some cases, the thermal and chemical stability of the reinforcements also poses problems in applications at medium and high temperatures and during heat treatments of these composites before they are put into service.

The object of the present invention is to enhance and utilize the reinforcing effects on various scales (nanoscale and microscale) and to activate mechanisms on the nanoscale (for example dislocation pinning, molecular chain immobilization, initiation of microcracks and cavities) and on the microscale (cavitation and crack propagation).

To obtain more satisfactory composites from the requirements standpoint, the inventors have thus developed a technique, using the CVD method, of growing carbon nanotubes that constitute nanoscale reinforcements having optimized morphologies and bonding, on supports corresponding to microscale reinforcements.

This technique makes it possible to modulate, depending on the envisaged application, the density, the length and the attachment of the CNTs to the supports.

The invention therefore provides a process for obtaining carbon nanotubes in situ in nanoscale/microscale supports.

The subject of the invention is also their use for producing composites and the applications of the latter.

According to the invention, the process for obtaining carbon nanotubes by growth, using the CVD method, on nanoscale/microscale supports, is characterized in that it comprises:
the addition of a compound as carbon source containing a catalyst, into a stream of inert gas and hydrogen.

According to one method of implementing the invention, the nanotubes are grown using a process characterized in that it also comprises:
the heating, in a reaction chamber, of a support material, to a temperature of 600-1100° C., in a stream of inert gas;
the cooling of the chamber down to room temperature; and
the recovery of the product formed.

The reaction chamber is advantageously a tube furnace with a gas circulation system.

The support material used is chosen from those capable of withstanding the CNT deposition temperature.

Advantageously, they are carbon fibers or a ceramic material preferably in the form of nanoscale/microscale particles or fibers.

As appropriate ceramic materials, the following may be mentioned: carbon fibers; glass fibers; SiC, TiC, Al₂O₃, SiO₂ or B₄C particles and fibers; silica fume; clays (clay particles); or wires comprising a metallic material such as Fe, Ni, Co, Ti, Pt, Au, Y, Ru, Rh, Pd, Zr, Cr or Mn.

With materials containing C, Si, Ti, B or Fe in their composition, it is possible to establish a strong bond between the CNTs and the supports by forming C—C, Si—C, Ti—C, B—C and Fe—C bridges.

For applications that require a particularly strong bond, heat treatments in a precise sequence may be applied after the deposition, so as to further consolidate (or strengthen) the adhesion.

The compound as carbon source is advantageously chosen from the following: liquid hydrocarbons of the group comprising xylene, toluene and benzene; or n-pentane; or alcohols, such as ethanol and methanol; or ketones, such as acetone. As a variant, the compound as carbon source is a gaseous hydrocarbon such as acetylene, methane, butane, propylene, ethylene and propene. As another variant, the compound as carbon source is solid, such as for example camphor.

As catalyst, it will be advantageous to have a compound chosen from the group comprising the following: an iron, cobalt or nickel metallocene; or else iron, cobalt or nickel nitrates, acetates or sulfates, especially Fe(II), phthalocyanine (FePc) and iron pentacarbonyl (Fe(CO)₅).

Preferably, the catalyst and the compound as carbon source are used in an amount from 0.001 to 0.1 g of catalyst per ml of compound.

The ratio of inert gas to hydrogen is 5/95 to 50/50.

By implementing the above arrangements, it is possible, by controlling the growth of the CNTs on the surface of the ceramic particles and fibers, or carbon fibers, to uniformly cover the ceramic supports and to improve the interfacial properties between the nanotubes and the supports as desired for a given application.

These properties may also be improved by subjecting the support material to a pretreatment step. In particular, the object of the invention is to provide a process for obtaining nanotubes by growth on supports which includes, before said step of heating the support material, the use of a silicon-containing compound under conditions allowing silicon or a silicon derivative, such as SiC, SiO or SiO₂, to be deposited on the surface of the supports.

The silicon-containing compound used is for example SiO or a silane, such as SiCl₄.

The products obtained are characterized in that they are multiscale composites formed from carbon nanotubes bonded to nanoscale/microscale carbon fiber or ceramic fiber support materials, as defined above.

These multiscale composites constitute reinforcements of great benefit for polymer, ceramic and metal matrices.

The presence of nanoscale reinforcements (of optimized density, length and bonding, depending on the matrices and the properties to be improved) makes it possible:
a) to reinforce the matrix close to the interface (conventional reinforcements/matrix interface);
b) to improve the adhesion between conventional reinforcements and the matrix;
c) to delay or prevent the initiation and propagation of damage and/or cracking at the interface; and
d) to reduce the difference (or the jump) in various properties between conventional reinforcements and the matrix, such as the thermal expansion coefficient and the mechanical properties, in order to prevent the generation of large residual stresses at the interface, especially during heat or mechanical cycles.

The subject of the invention is also composites characterized in that they comprise CNTs bonded to nanoscale/microscale supports in a matrix.

The manufacture of the composites is adapted according to the type of matrix.

For composites having a ceramic or brittle matrix, short CNTs of relatively low density must be deposited on the surface of the conventional reinforcements in order to obtain an intimate contact between the surface of the conventional reinforcements and the matrix. This therefore results in mechanical anchoring of the CNTS attached to the surface of the conventional reinforcements.

In the case of composites with a ductile (metal or polymer) matrix, long CNTs of relatively high density must be deposited on the surface of the conventional reinforcements. What is employed is a process of the infiltration type, optionally under pressure (for infiltration of liquid polymers and metals) in order to obtain intimate contact between the surface of the conventional reinforcements and the matrix. Two reinforcement mechanisms are possible. The first involves mechanical anchoring, thanks to the presence of the CNTs having strong bonding between them and the surface, while the second mechanism is the immobilization of the molecular chains in the case of polymeric matrices and the pinning of dislocations in the case of metal matrices and crystallized polymeric matrices. This second mechanism is particularly effective with nanoscale reinforcements. The CNTs obtained according to the invention are therefore particularly appropriate, given that they are conveyed by the conventional reinforcements and well dispersed in the matrices.

Such composites are particularly appropriate in the fields of structural materials, the protection of materials, the functionalization and improvement of surfaces, selective filtration or separation, the manufacture of flat screens and field-emission screens, and for hydrogen storage. Mention may also be made of optical, thermal and stealth applications. It should be noted with interest that the products of the invention are less volatile than the CNTs obtained hitherto, which makes them advantageous with regard to safety regulations.

In general, the multiscale multifunctional composites of the invention can therefore be used in many applications:
the microscale/nanoscale materials may be added to nanoscale/microscale supports covered with nanotubes in polymer, ceramic of metal matrices;
the ceramic matrix composites may be obtained by compacting the nanoscale/microscale supports covered with nanotubes; and
these composites may, where appropriate, be functionalized and used for the selective filtration or separation of fluids, gases or the like.

The supports covered with carbon nanotubes may furthermore be used as field-emission tips.

The growth of CNTs on supports, as indicated above, for example on fuels or explosive powders, makes it possible to improve these materials or to give them novel properties leading to novel applications.

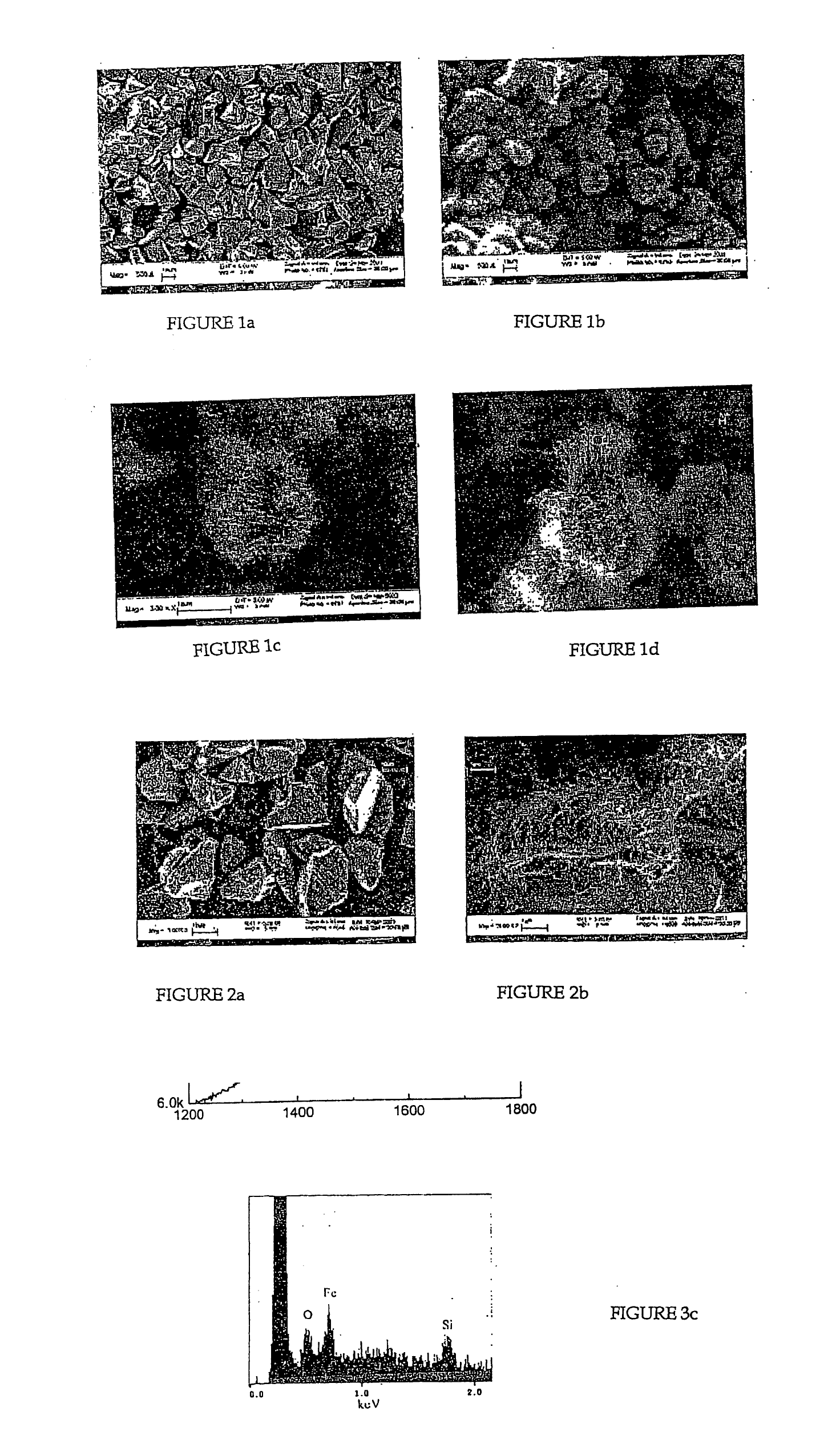

Other features and advantages of the invention will be given in the following examples that refer to FIGS. 1 to 10, which show SEM micrographs of, respectively:

FIG. 1a: raw SiC particles; FIG. 1b: SiC particles with a carbon nanotube coating, at low magnification; FIGS. 1c and 1d: an enlargement of two SiC particles coated with carbon nanotubes;

FIG. 2a: SiC particles with a less dense coating of carbon nanotubes; FIG. 2b: a zoom on SiC particles with a dispersed growth of shorter carbon nanotubes from the surface;

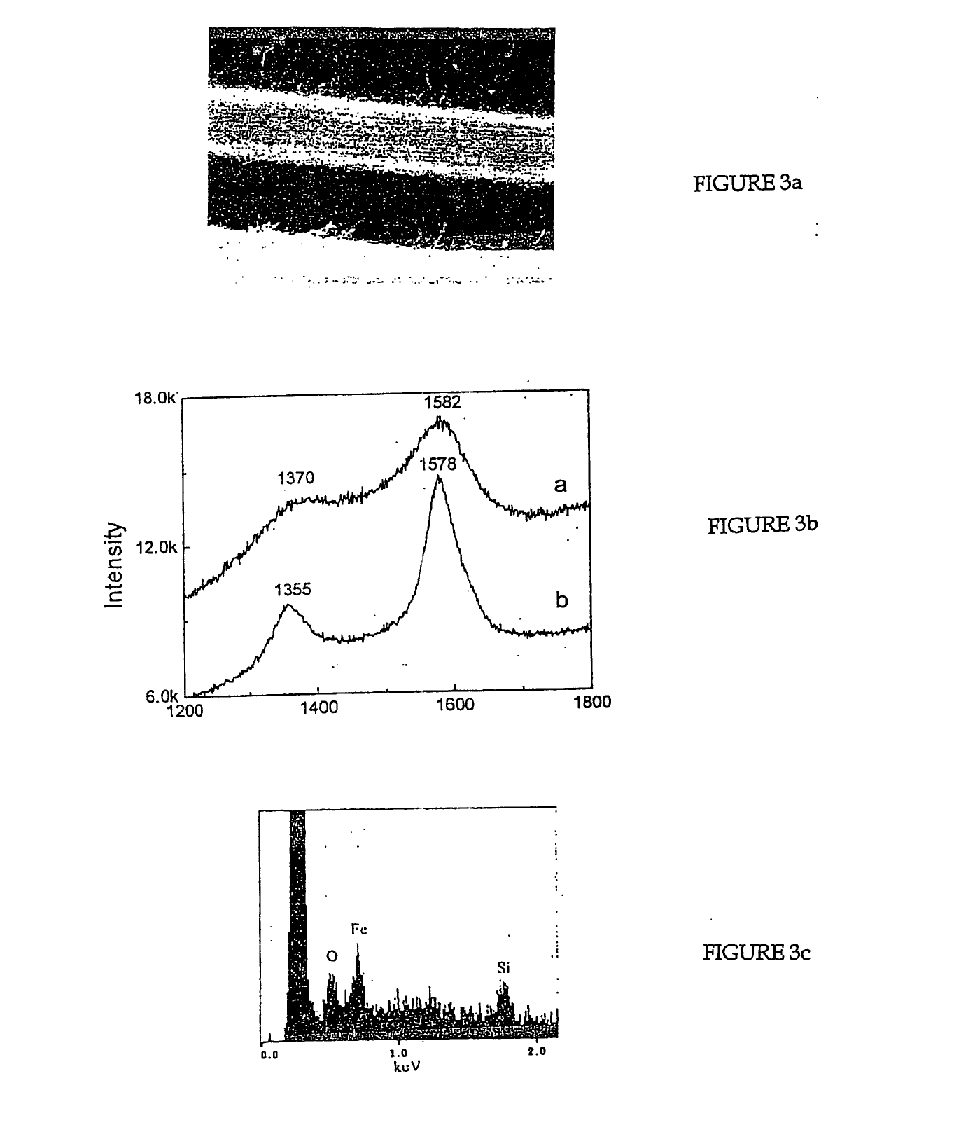

FIG. 3a: carbon fibers having undergone a pretreatment according to the invention; FIG. 3b: their Raman spectrum; FIG. 3c: their EDX spectrum;

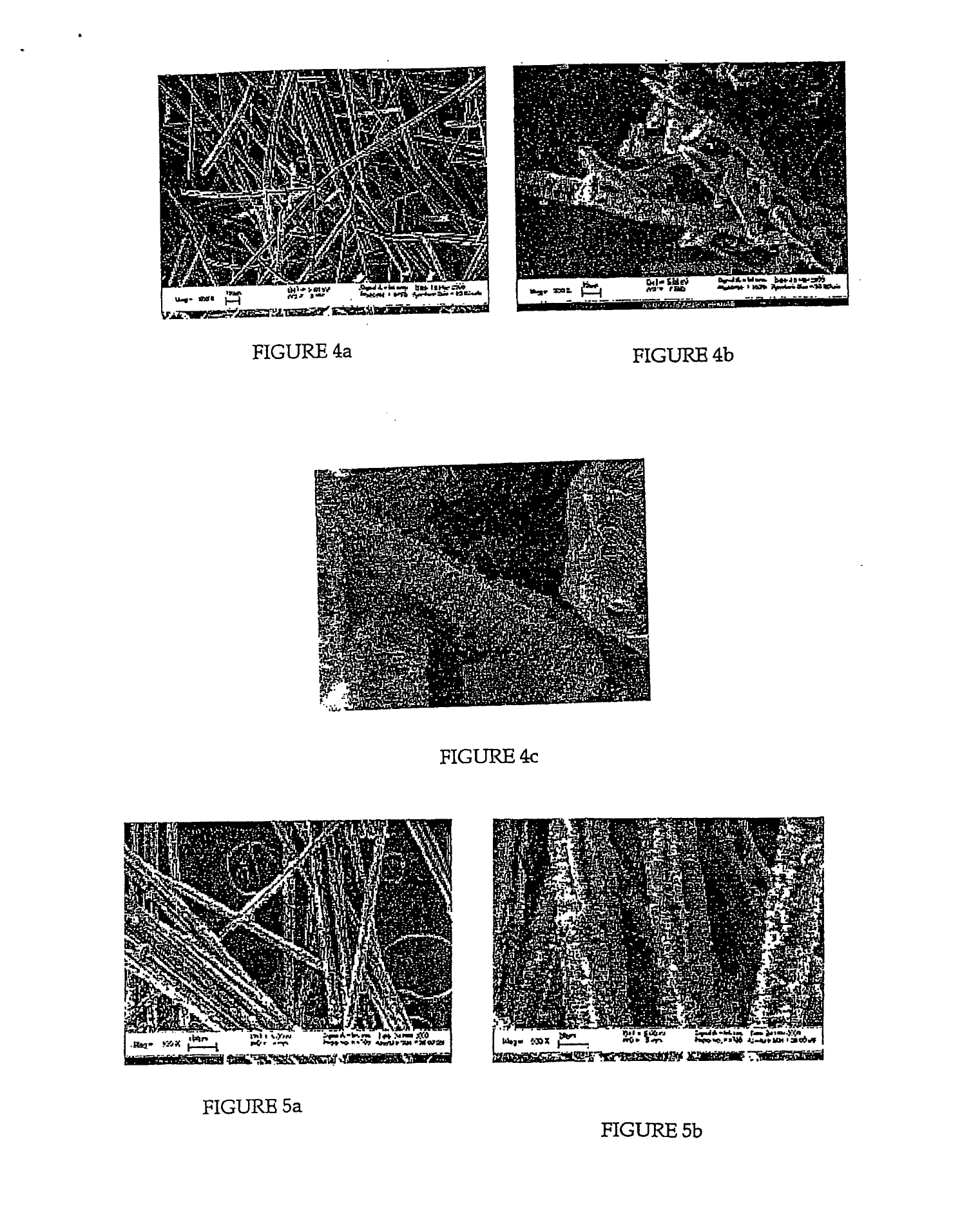

FIG. 4a: raw Al₂O₃ fibers; FIG. 3b: a slight enlargement of Al₂O₃ fibers coated with carbon nanotubes; FIG. 4c: a zoom on Al₂O₃ fibers with a coating of longer carbon nanotubes;

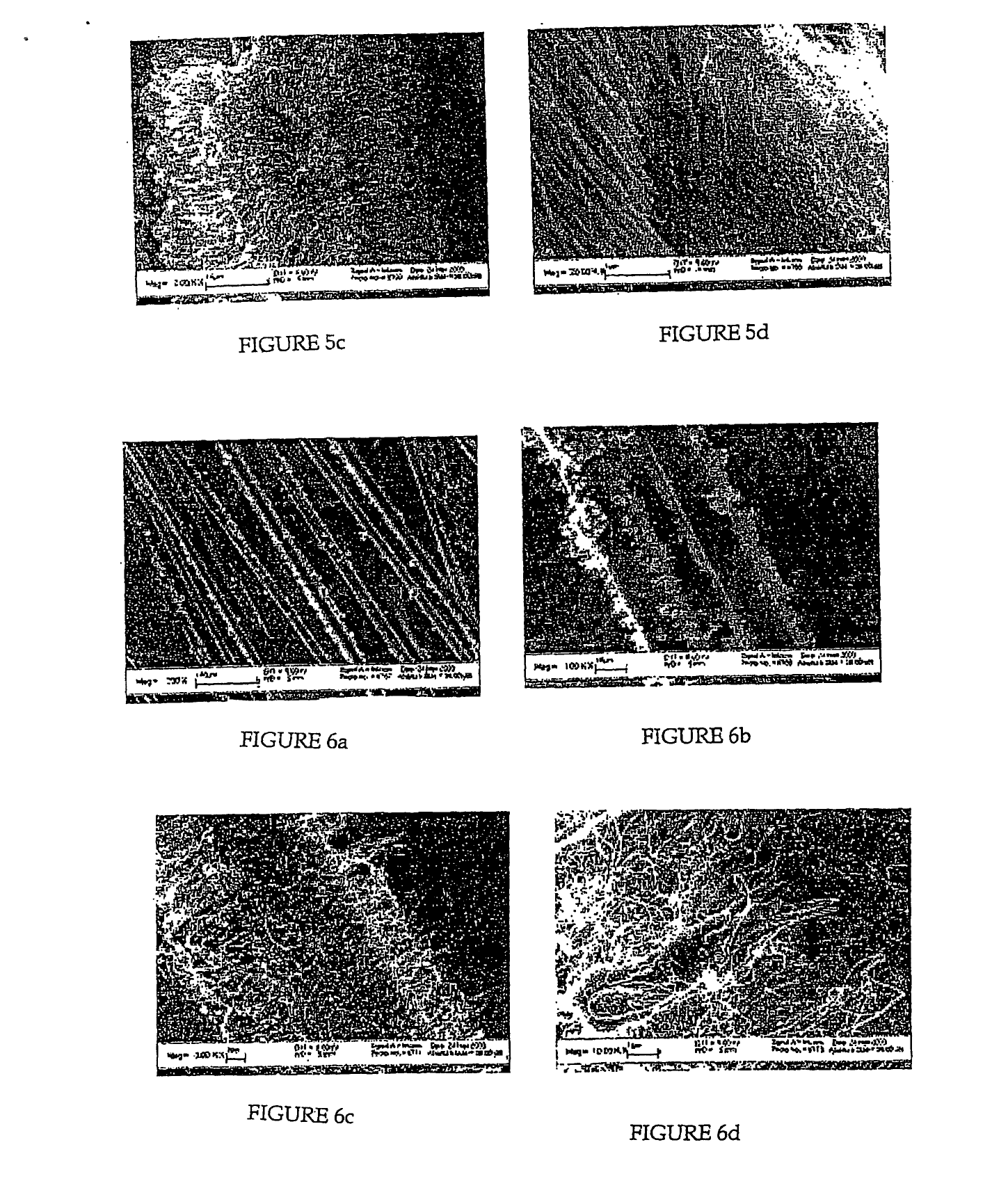

FIGS. 5a to 5c: SiC fibers with a coating of aligned nanotubes; FIG. 5d: nanotubes with growth perpendicular to the surface of the SiC fibers;

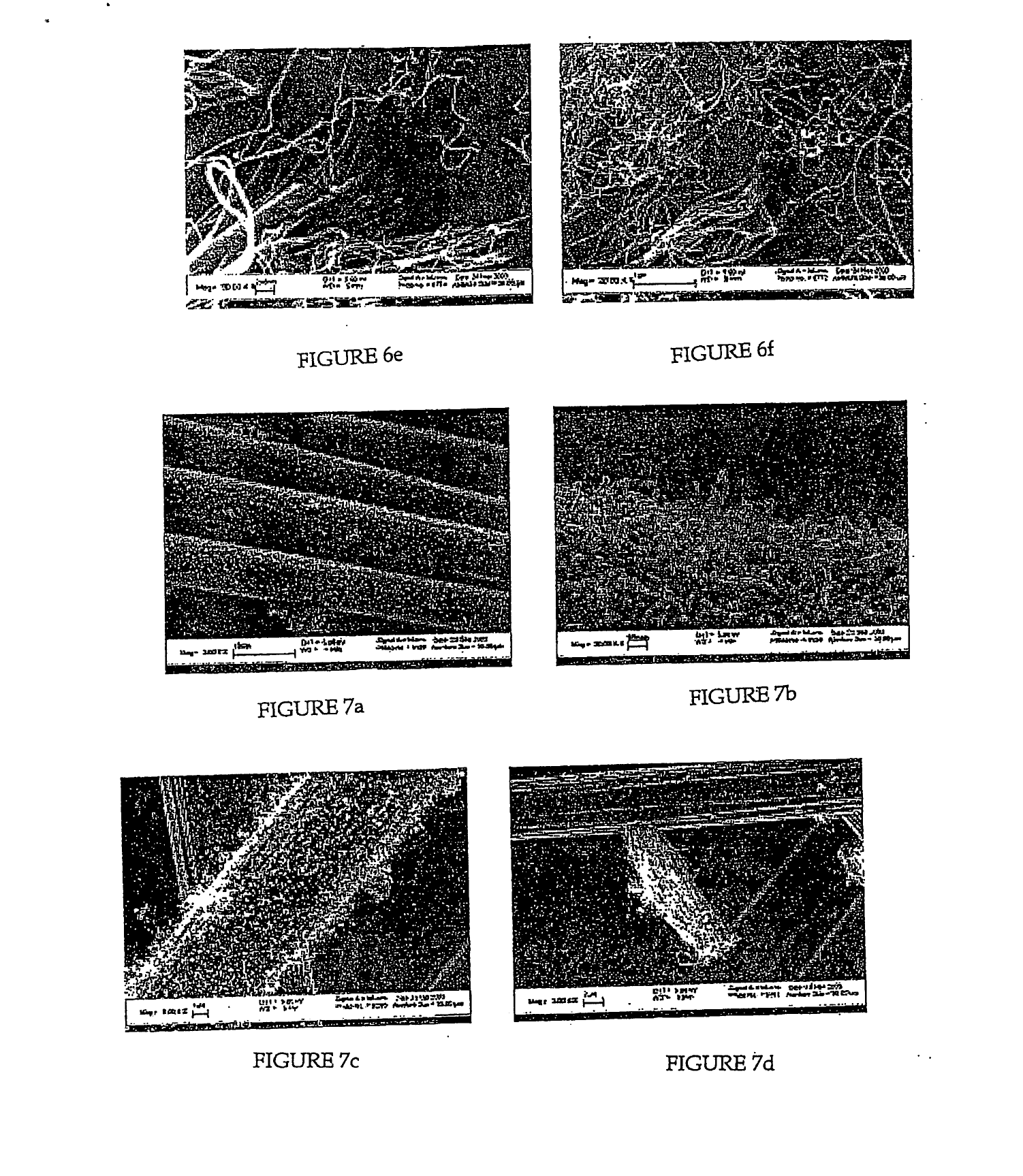

FIGS. 6a and 6b: SiC fibers with a less dense coating of carbon nanotubes; FIG. 6c: columns that have grown at certain points; FIG. 6d: an enlargement showing the carbon nanotubes enveloped in the columns; FIG. 6e: the base of the column; FIG. 6f: a small faggot of carbon nanotubes enveloped at their base;

FIGS. 7a and 7b: carbon fibers coated with short carbon nanotubes; FIG. 7c: carbon fibers coated with fibers of very long carbon nanotubes (growth at 900° C.); and FIG. 7d: faggots of aligned carbon nanotubes with growth at certain locations on oxidized carbon fibers;

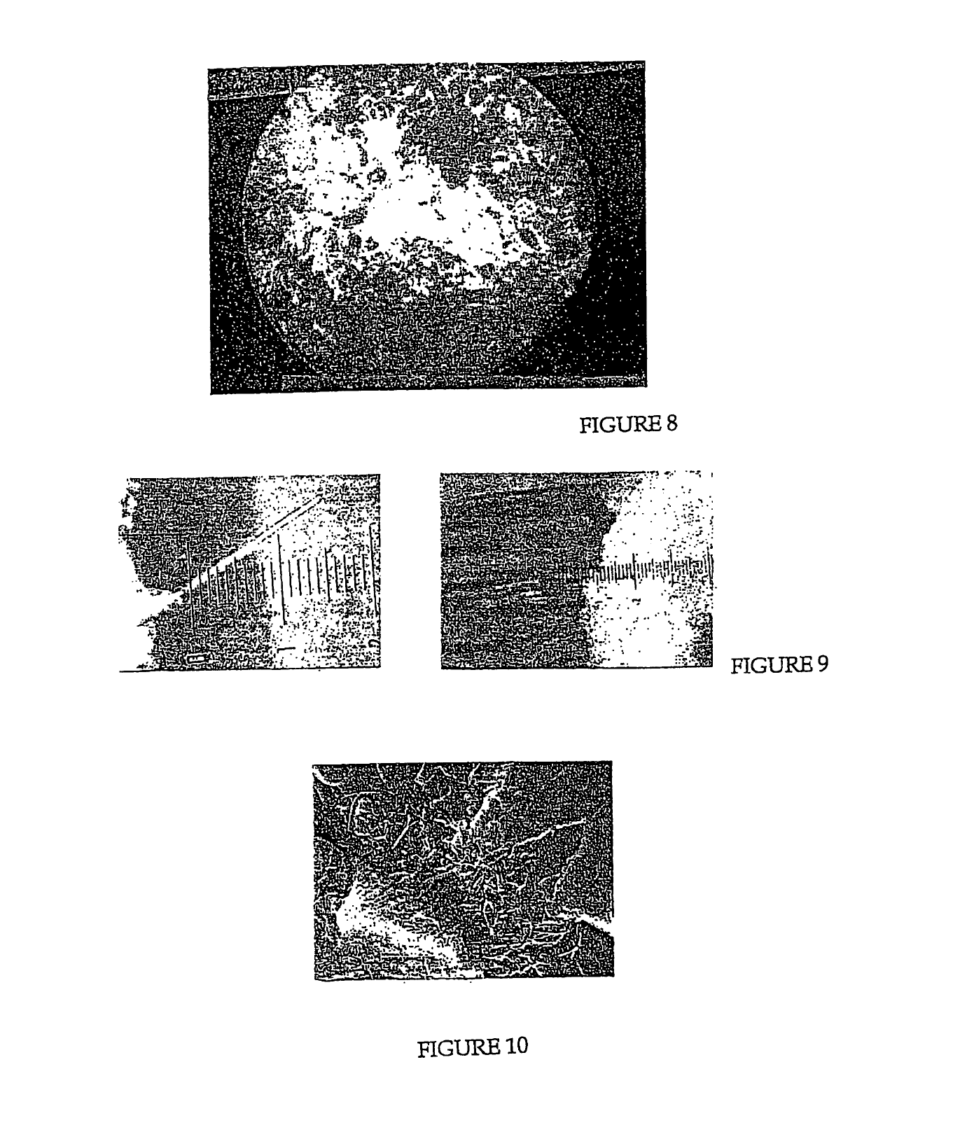

FIG. 8: nanotubes on a silica fume support;

FIG. 9: composites comprising a resin and long carbon fibers with and without CNT;

FIG. 10: a composite comprising a resin and SiCₚ with and without CNT;

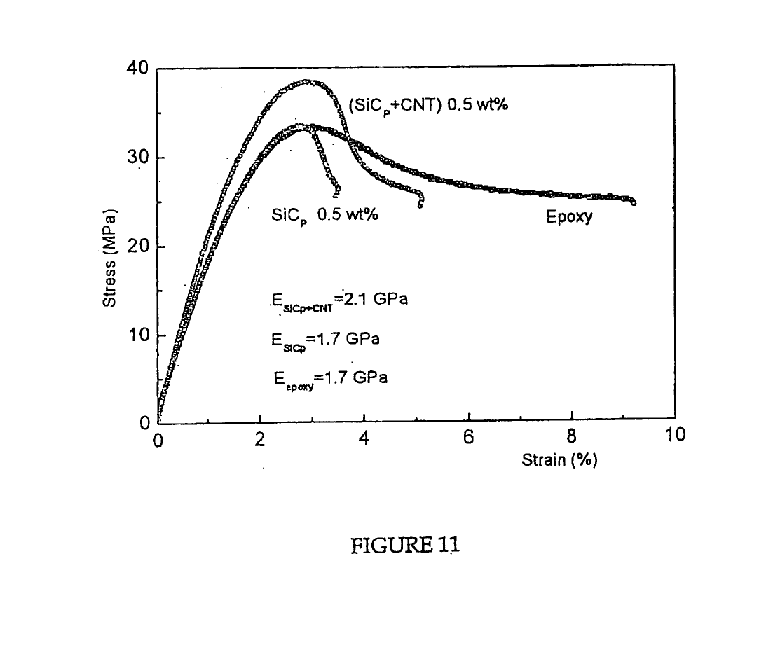

FIG. 11: comparative tensile curves for 0.5 wt % SiCₚ, epoxy resin, and 0.5 wt % (SiCₚ+CNT); and

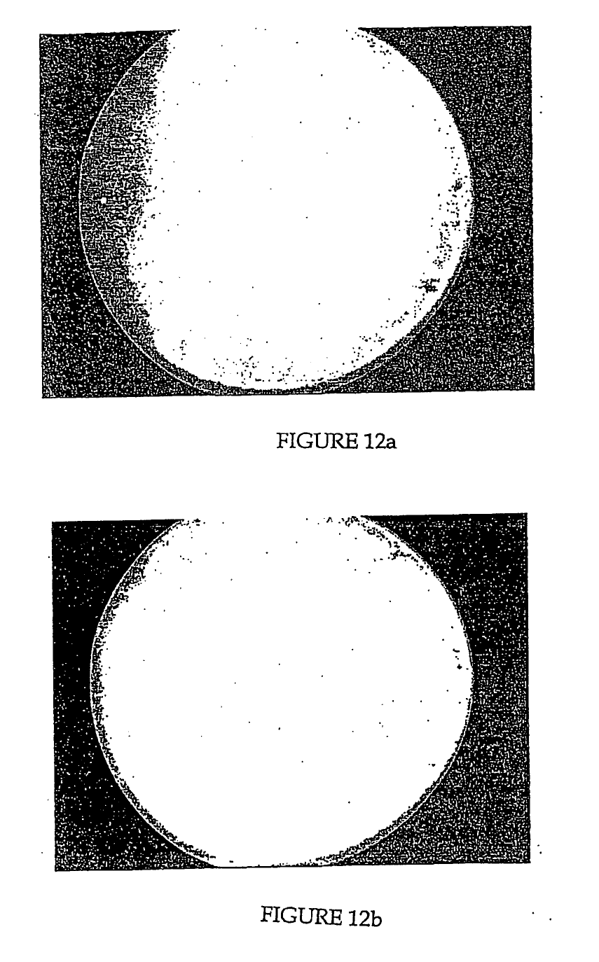

FIGS. 12a and 12b: a clay particle (FIG. 12a) and a glass fiber (FIG. 12b) with a coating of nanotubes.

The results of experiments carried out as follows are given below:

General Experimental Protocol

The device used comprised:
an electric furnace 75 cm in length, equipped with a quartz tube of 40 mm inside diameter; and
two tubes, located at the entry of the reactor, of different inside diameters, namely 4 mm and 0.5 mm respectively, one of the tubes being used for introducing gas and the other for introducing the compounds employed.

The smaller-diameter tube was inserted into the larger-diameter tube, thereby allowing it to be cooled by the flow of gas passing through the larger-diameter tube and making it easier to control the flow of the liquid compounds.

The inlets of the two tubes were connected in a zone at a temperature of 150-300° C.

In these experiments, the carbon source consisted of xylene and the catalyst of ferrocene (Fe(C₅H₅)₂).

The ceramic, carbon fiber, SiC, TiC, Al₂O₃ and SiO₂ particles and fibers, silica fume and B₄C were placed in a ceramic container, which was then positioned at the center of the quartz tube.

The furnace was then heated up to the growth temperature of 600-1100° C.

During the temperature rise in the furnace, a stream of nitrogen was made to flow through the reactor at a flow rate of 100 to 2000 ml/min. When the growth temperature was reached, instead of a stream of nitrogen an N₂/H₂ gas mixture was used, with a 10/1 ratio and a flow rate of up to 1650 ml/min.

A mixture of ferrocene in xylene, in an amount of 0.001-0.1 g of ferrocene per ml of xylene, was injected at a flow rate of 0.02-0.3 ml/min.

The growth time was generally a few tens of minutes, depending on the density and the length of the nanotubes desired, especially 10 to 30 minutes.

The above cycle could be followed by heat sequences in order to improve, if desired, the adhesion between the nanotubes and the supports.

The furnace was then cooled down to room temperature, under a 500 ml/min stream of nitrogen, and the product recovered from the reactor.

Pretreatment of Carbon Fibers with SiO

Before the carbon source was introduced, the support material was treated at a high temperature with SiO in the following manner:

Commercial SiO powder was introduced into a ceramic container. The carbon source product was then placed on the SiO powder. The furnace was heated up to a temperature of 1150° C. in a stream of nitrogen (500 sccm) and maintained at this temperature for 6 h.

Nanotubes on the Surface of SiC Particles

FIG. 1a shows a micrograph of the SiC particles used in the process of the invention. These particles had a diameter of about 10 μm and an irregular shape, mostly with one or more plane surfaces. The SiC powder was placed on a flat ceramic container with a thickness of about 0.5 mm. After the carbon nanotubes had been grown on their surface, the SiC powder became black and the particles formed flakes that could be easily removed from the ceramic container, thereby demonstrating that the carbon nanotubes grow uniformly at the surface of all the SiC particles.

The SEM observation confirmed these results.

FIG. 1b is an SEM micrograph at low magnification of a product obtained according to the invention, with a growth time of 25 min.

Practically all the SiC particles are densely coated with carbon nanotubes. The length of the carbon nanotubes depends on the growth time. 10-20 μm nanotubes were obtained with a growth time of 25 min.

FIGS. 1c and 1d show micrographs zooming in on one particle. It may be seen that the carbon nanotubes are aligned and perpendicular to the upper flat surface. On other surfaces, the nanotubes do not appear to be aligned and their density is also lower. This demonstrates that the growth of the carbon nanotubes on SiC is selective, depending on the various faces of the crystal.

The density and the length of the carbon nanotubes could be controlled by experimental parameters, such as the growth time and the ferrocene content of the xylene solution.

Denser and longer carbon nanotubes are able to be obtained on the surface of SiC particles with longer durations and higher ferrocene contents.

FIG. 2a shows a specimen with a lower density of carbon nanotubes (the growth time was in this case 15 min) and FIG. 2b shows a corresponding enlargement. The carbon nanotubes grown have a length of a few μm and appear to be of low density.

Nanotubes on the Surface of Carbon Fibers that have Undergone a Pretreatment According to the Invention

The procedure was as indicated in the general conditions given above.

As illustrated in FIG. 3a, the nanotubes are grown easily on the pretreated carbon fibers. These results were reproducible when temperatures below about 750-850° C. were used. Examination of FIG. 3a shows that the nanotubes are distributed uniformly in the coating and are entangled. The thickness of the coating varies from 400 to 1000 nm. Under SEM examination, it was observed that very few particles were attached to the surface of the carbon fibers, showing that the SiO-treated surface is activated in order to form a support for the catalyst particles for growth of the nanotubes.

Observation under TEM (FIG. 3b) shows that the coating is formed from high-quality carbon nanotubes with a diameter of 20 to 30 nm. The Raman spectrum also shows that the carbon nanotubes obtained are highly graphitized (FIG. 3b), in which the principle Raman peaks observed are at 797 and 972 cm⁻¹. The results of the EDX study (FIG. 3c) show that the elements Si and O exist on the surface of the carbon fibers that have undergone the pretreatment, with or without coating of carbon nanotubes, demonstrating that the SiO coating forms after the treatment.

Nanotubes on the Surface of Al₂O₃ Fibers

FIG. 4a shows a micrograph of Al₂O₃ fibers before the growth of carbon nanotubes.

These fibers have a diameter of 2-7 μm and a length of 10 μm. SEM examination indicates that their surface is very smooth.

Using the same experimental conditions as with the SiC particles, a dense growth of aligned carbon nanotubes was obtained on the surface of the Al₂O₃ fibers, as illustrated by FIGS. 4b-d.

These show a uniform coverage over the entire surface of the Al₂O₃ fibers with carbon nanotubes, even at the two ends.

The diameter of the carbon nanotubes appears to be lower than in the SiC case.

As illustrated in FIG. 4c, the carbon nanotubes have a tendency to curve over on one side of the Al₂O₃ fiber owing to the flexible nature of the smaller-diameter nanotubes.

Nanotubes on the Surface of SiC Fibers

Continuous NLM-Nicalon fibers with a diameter of about 10 μm were used. These fibers were chopped into shorter fibers and placed in a ceramic container.

FIG. 5 shows micrographs of these fibers with a carbon nanotube coating obtained with a growth temperature of 700° C. and a growth time of 30 min. The ferrocene/xylene mixture was injected at a rate of about 0.05 ml/min and the total quantity of gas (N₂/H₂=10/1) was 1650 ml/min.

It may be seen that the carbon nanotubes are aligned and cover a large part of the surface of the SiC fibers.

The thickness of the carbon nanotubes is about 15 μm, indicating that the nanotube growth rate was about 0.5 μm/min.

FIGS. 5a, b and c are SEM micrographs of SiC fibers with aligned carbon nanotube coatings.

FIG. 5d shows an SEM micrograph indicating that the carbon nanotubes grow perpendicularly from the surface of the SiC fibers and that they have the same length.

It is apparent that few catalyst particles are attached to the root of the nanotubes, indicating that the main mechanism of growth of the nanotubes on the SiC fiber support is of the type in which growth takes place via the end.

It is therefore easy to control the density of the nanotube alignments by regulating the ferrocene content in the xylene solution. It is also easy to adjust the thickness of the coating by changing the growth time.

FIGS. 6a to 6f correspond to SEM micrographs of a product for a growth time of 15 min. They show that the surface of the SiC fibers is not completely coated with aligned nanotubes. Thus, in FIGS. 6b and c, a few parts of the surface are covered with a low density of entangled nanotubes. At a few places, irregular columns 4-5 μm in height grow on the surface of the fiber.

Examination of FIG. 6d also shows that many nanotubes are enveloped in these columns and that their base is strongly attached to the surface of the fiber (FIG. 6e).

In FIG. 6f, the root of a small bundle of nanotubes is just enveloped, demonstrating that the contact interface between the nanotubes and the fiber is very strong at these points.

Nanotubes on the Surface of Carbon Fibers

A quartz sheet was placed in the middle of the tube, and the carbon fibers placed on said sheet.

Before the reaction solution was injected, the carbon fibers were preheated to a temperature of at least 700° C., in the stream of nitrogen, in order to eliminate any polymer around the fiber.

The solution prepared was injected sequentially into the furnace for all the reaction times, at different injection rates of 0.05 ml/min to 0.2 ml/min, and the temperature of the reaction was maintained at 600-900° C.

FIGS. 7a and 7b show the SEM images of nanocomposites consisting of carbon fibers and very short dispersed multi-walled nanotubes, which grew at 700° C. with a growth time of 30 min. The diameter of the carbon fibers before growth of the multi-walled nanotubes by CVD was 7 μm and the diameter of the carbon fibers after growth of the multi-walled nanotubes was 8-8.5 μm, so that the thickness of the region of multi-walled nanotubes surrounding the fiber was around 0.5 to 0.75 μm.

The enlarged view of the nanotubes shows that the majority of the multi-walled nanotubes are upwardly oriented, but they are not vertical (FIG. 7b).

The length of the multi-walled nanotubes is about 0.2 to 0.7 μm and the outside diameter is about 80-100 nm.

FIG. 7c shows a carbon fiber with a very long coating of nanotubes (its growth temperature was 900° C.). To improve the growth of the nanotubes on carbon fibers, these fibers were subjected to a heat treatment in air and the nanotubes were grown on these treated fibers. As shown in FIG. 7d, faggots of aligned nanotubes were able to grow a few places on the oxidized carbon fibers.

Nanotubes on Silica Fume Particles

The procedure was as indicated above, using microsilica (silica fume). FIG. 8 shows the nanotubes grown on the microsilica particles according to the procedure as indicated above.

Production of CNT/Ceramic/Matrix Composites

Two types of composites were used:
1. Composites consisting of resin and long carbon fibers with and without CNT: debonding was observed with conventional carbon fibers (T300 type, 7 μm in diameter) impregnated with epoxy resin without the CNT coating, but no debonding on the fibers with this coating (FIG. 9).
2. Composites consisting of resin and SiCₚ with and without CNT: after mixing with the resin, it was found that the CNTs always remained around the SICₚs (FIG. 10). The fracture surfaces of the composites (resin, SiCₚ and NTs) showed a smooth surface on SiCₚs without nanotubes, whereas fracture took place in the matrix when CNT-coated SiCₚs were used. FIG. 9 shows that good SiCₚ/CNT dispersion is obtained. The comparative tensile curves are given in FIG. 11. A remarkable reinforcement effect is obtained with 0.5 wt % SiCₚ/CNT, compared with the same amount of SiCₚ.

Composites with a matrix made of an Mg alloy and of an Al alloy containing CNT-coated SiCₚs were also studied.

Nanotubes on a Clay Particle Support

FIG. 12a illustrates the nanotubes deposited on such a support using the procedure according to the invention.

Nanotubes on a Glass Fiber Support

FIG. 12b illustrates such a support with a nanotube coating.

1. A process for obtaining carbon nanotubes by growth, using the CVD method, on nanoscale/microscale supports, characterized in that it comprises:
the addition of a compound as carbon source containing a catalyst, into a stream of inert gas and hydrogen.

2. The process as claimed in claim 1, characterized in that it also gcomprises:
the heating, in a reaction chamber, of a nanoscale/microscale ceramic material or of carbon fibers, to a temperature of 600-1100° C., in a stream of inert gas;
the cooling of the chamber down to room temperature; and
the recovery of the product formed.

3. The process as claimed in claim 2, characterized in that the ceramic material is in the form of nanoscale/microscale particles or fibers.

4. The process as claimed in claim 3, characterized in that the ceramic material is formed from the following: carbon fibers; glass fibers; SiC, TiC, Al₂O₃, SiO₂ or B₄C particles and fibers; silica fume; clays (clay particles); or wires comprising a metallic material such as Fe, Ni, Co, Ti, Pt, Au, Y, Ru, Rh, Pd, Zr, Cr or Mn.

5. The process as claimed in claim 1, characterized in that the compound as carbon source is chosen from the following: liquid hydrocarbons of the group comprising xylene, toluene and benzene; or n-pentane; or alcohols, such as ethanol and methanol; or ketones, such as acetone; or, as a variant, the compound as carbon source is a gaseous hydrocarbon such as acetylene, methane, butane, propylene, ethylene and propene; or the compound as carbon source is solid, such as for example camphor.

6. The process as claimed in claim 1, characterized in that the catalyst is chosen from the group comprising the following: an iron, cobalt or nickel metallocene; or else iron, cobalt or nickel nitrates, acetates or sulfates, especially Fe(II), phthalocyanine (FePc) and iron pentacarbonyl (Fe(CO)₅).

7. The process as claimed in claim 1, characterized in that the catalyst and the compound as carbon source are used in an amount from 0.001 to 0.1 g of catalyst per ml of compound.

8. The process as claimed in claim 1, characterized in that the ratio of inert gas to hydrogen is 5/95 to 50/50.

9. The process as claimed in claim 1, characterized in that, before said step of heating the support material, a silicon-containing compound is used under conditions allowing silicon or a silicon derivative, such as SiC, SiO or SiO₂, to be deposited on the surface of the support material.

10. The process as claimed in claim 9, characterized in that the silicon-containing compound used is SiO or a silane, such as SiCl₄.

11. Products thus obtained by the process as claimed in claim 1, characterized in that they are multiscale composites formed from carbon nanotubes bonded to nanoscale/microscale carbon fiber or ceramic fiber support materials.

12. Multiscale composites, characterized in that they comprise carbon nanotubes bonded to nanoscale/microscale supports in a polymer, metal or ceramic matrix.
